(19) United States
(12) Patent Application Publication
(10) Pub. No.: US 2025/0014775 A1
(43) Pub. Date: Jan. 9, 2025

(54) CONDUCTIVE FILM AND DISPLAY DEVICE

(71) Applicant: TDK Corporation, Tokyo (JP)

(72) Inventors: Hiroshi SHINGAI, Tokyo (JP); Keisuke NISHIOKA, Tokyo (JP); Haruna OGAWA, Tokyo (JP); Shinsuke HASHIMOTO, Tokyo (JP)

(73) Assignee: TDK Corporation, Tokyo (JP)

(21) Appl. No.: 18/897,160

(22) Filed: Sep. 26, 2024

Related U.S. Application Data
(63) Continuation of application No. PCT/JP2023/008423, filed on Mar. 6, 2023.

(30) Foreign Application Priority Data
Mar. 29, 2022 (JP) 2022-053996

(51) Int. Cl. H01B 1/22; H01B 17/64

(52) U.S. Cl. CPC H01B 1/22; H01B 17/64

(57) ABSTRACT

A conductive film including a film-like base material and a conductive layer provided on one main surface side of the base material is provided. The conductive layer includes a first metal layer containing a first metal and a second metal layer containing a second metal different from the first metal, provided in order from the base material side. The first metal layer includes grain boundaries.

### CROSS-REFERENCE TO RELATED APPLICATIONS

This application is a bypass continuation of International Patent Application No. PCT/JP2023/008423, filed on Mar. 6, 2023, which claims the benefit of priority based on Japanese Patent Application No. 2022-053996 filed on Mar. 29, 2022, and the entire contents of the above-mentioned applications are incorporated herein by reference.

### TECHNICAL FIELD

The present disclosure relates to a conductive film and a display device.

### BACKGROUND ART

A transparent antenna having a conductive substrate (conductive film) that is transparent and conductive is sometimes mounted on a surface of a touch panel or a display. Recently, as touch panels and displays have become larger and more diverse, conductive films are required to have flexibility as well as high transparency and conductivity.

As the conductive substrate, for example, Patent Literature 1 discloses a conductive substrate including a base material, an underlayer, a trench forming layer, and a conductive pattern layer, and the underlayer has a mixed region which is formed from a surface of the underlayer on the conductive pattern layer side to the inside thereof and contains a metal constituting the conductive pattern layer and metal particles embedded in the underlayer. It is also disclosed that the conductive pattern layer can be formed by a plurality of metal layers.

### CITATION LIST

### Patent Literature

[Patent Literature 1] Japanese Patent Application Laid-Open No. 2019-29658

### SUMMARY

An aspect of the present disclosure relates to a conductive film including a film-like base material and a conductive layer provided on one main surface side of the base material. In the conductive film, the conductive layer contains a first metal layer and a second metal layer provided in order from the base material side. The first metal layer includes grain boundaries.

Another aspect of the present disclosure relates to a display device including a conductive film.

### BRIEF DESCRIPTION OF DRAWINGS

FIG. 1 is a schematic plan view showing a conductive film according to an embodiment.

FIG. 2 is a cross-sectional view taken along a line II-II of FIG. 1.

FIG. 3 is a partially enlarged view of the conductive film shown in FIG. 2.

FIG. 4A is a cross-sectional view schematically showing a method for manufacturing the conductive film shown in FIG. 1.

FIG. 4B is a cross-sectional view schematically showing a method for manufacturing the conductive film shown in FIG. 1.

FIG. 4C is a cross-sectional view schematically showing a method for manufacturing the conductive film shown in FIG. 1.

FIG. 4D is a cross-sectional view schematically showing a method for manufacturing the conductive film shown in FIG. 1.

FIG. 5A is a cross-sectional view schematically showing a method for manufacturing the conductive film shown in FIG. 1.

FIG. 5B is a cross-sectional view schematically showing a method for manufacturing the conductive film shown in FIG. 1.

FIG. 5C is a cross-sectional view schematically showing a method for manufacturing the conductive film shown in FIG. 1.

FIG. 6A is a cross-sectional view schematically showing a method for forming a metal layer of the conductive film shown in FIG. 1.

FIG. 6B is a cross-sectional view schematically showing a method for forming a metal layer of the conductive film shown in FIG. 1.

FIG. 6C is a cross-sectional view schematically showing a method for forming a metal layer of the conductive film shown in FIG. 1.

FIG. 7 is a cross-sectional view showing an embodiment of a display device.

### DESCRIPTION OF EMBODIMENTS

### Problem to be Solved by the Present Disclosure

For the conductive film including a conductive layer composed of a plurality of metal layers, it is required to improve the adhesion between the metal layers.

### Effect of the Present Disclosure

For the conductive film including a conductive layer composed of a plurality of metal layers, the adhesion between the metal layers can be improved.

The present disclosure is not limited to the following examples.

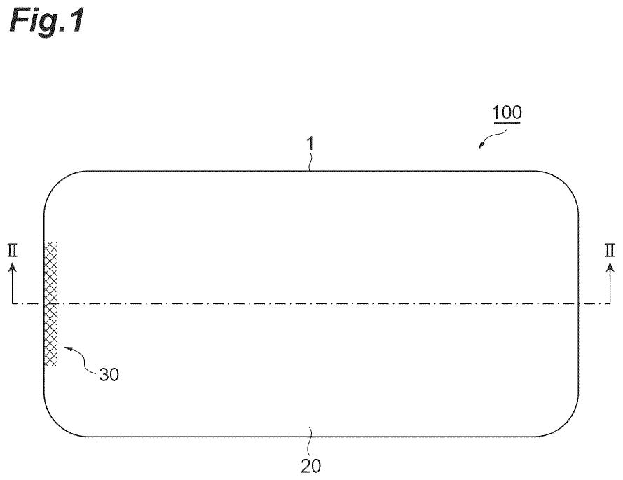

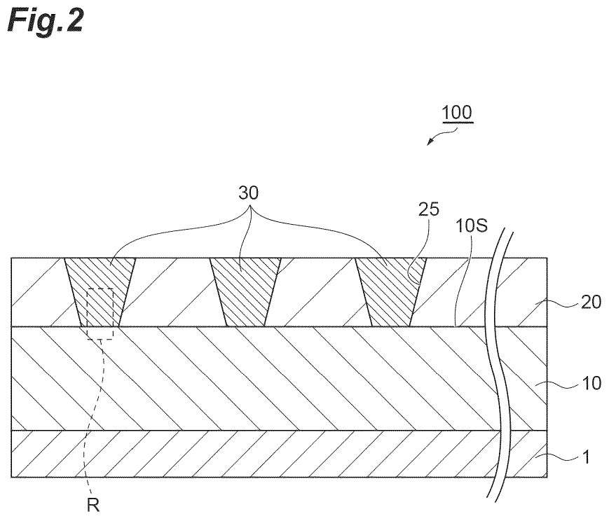

FIG. 1 is a schematic plan view showing a conductive film according to an embodiment. FIG. 2 is a cross-sectional view taken along a line II-II of FIG. 1. A conductive film 100 shown in FIGS. 1 and 2 includes a film-like base material 1, a first resin layer 10 which is provided on the base material 1, a second resin layer 20 which is provided on the first resin layer 10 and has a linear trench 25 opening to a surface opposite to the first resin layer 10, and a conductive layer 30 which is provided on the trench 25. In FIGS. 1 and 2, a mesh-like pattern is formed by a plurality of the linear trenches 25 extending in each of the two directions intersecting with each other. The conductive layer 30 in the trench 25 also forms a mesh-like pattern. The conductive layer 30 having a mesh-like pattern can function well as, for example, a radiating element of an antenna. The trench 25 and the conductive layer 30 are provided over a partial region of a surface 10S of the first resin layer 10.

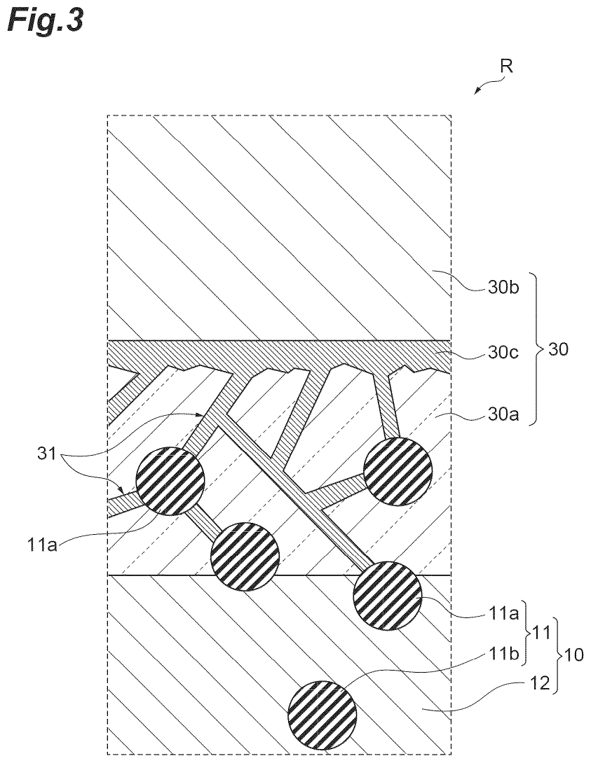

FIG. 3 is an enlarged view of a region R in the cross-sectional view of the conductive film 100 shown in FIG. 2. As shown in FIG. 3, the conductive layer 30 includes a first metal layer 30a containing a first metal, a third metal layer 30c containing a third metal, and a second metal layer 30b containing a second metal in order from the side of the base material 1. The first metal, the second metal, and the third metal are different metals. Each of the first metal, the second metal, and the third metal may be one type of metal or a combination of two or more types of metals. The first metal layer 30a may further contain the second metal and/or the third metal, the second metal layer 30b may further contain the first metal and/or the third metal, and the third metal layer 30c may further contain the first metal and/or the second metal. The first metal layer 30a, the second metal layer 30b, and the third metal layer 30c may further contain a nonmetallic element such as phosphorus, as long as the conductivity is maintained.

The first metal constituting the first metal layer 30a may be, for example, at least one selected from the group consisting of nickel, gold, silver, copper, and palladium, or may be nickel.

The first metal layer 30a includes a plurality of crystal grains, and grain boundaries 31 that are boundaries between the crystal grains are formed in the first metal layer 30a. When the grain boundaries 31 are formed, the surface area of the first metal layer 30a increases, which can contribute to improving the adhesion between the first metal layer 30a and other metal layers. The formation of the grain boundaries 31 can be confirmed, for example, by observing a cross section of the conductive film 100 along the thickness direction with a transmission electron microscope (TEM). In elemental mapping of the first metal layer 30a, the grain boundaries 31 may be observed as linear regions in the first metal layer 30a where the first metal is substantially not observed. In that case, the first metal layer 30a may be divided into a plurality of regions by the grain boundaries 31. The individual regions divided by the grain boundaries 31 are considered to correspond to crystal grains, and the maximum width thereof may be, for example, 10 nm or more or 20 nm or more and 100 nm or less or 80 nm or less.

The thickness of the first metal layer 30a may be 10 nm or more, 20 nm or more, or 30 nm or more from the viewpoint of high adhesion between the first metal layer 30a and other metal layers (for example, the third metal layer 30c). From the viewpoint of high conductivity as the conductive layer 30, the thickness of the first metal layer 30a may be 200 nm or less, 100 nm or less, or 90 nm or less. The thickness of the portion of the conductive layer 30 that contains the first metal can be considered as the thickness of the first metal layer 30a.

The second metal constituting the second metal layer 30b may be, for example, at least one type selected from the group consisting of copper, gold, silver, and palladium, or may be copper.

The second metal may also be present in the grain boundaries 31 in the first metal layer 30a. That is, the metal component of the second metal may penetrate the grain boundaries 31 in the first metal layer 30a. The second metal may be distributed continuously from the second metal layer 30b to the grain boundaries 31 in the first metal layer 30a. The second metal present in the grain boundaries 31 can be considered as a part of the first metal layer 30a. The presence of the second metal at the grain boundaries 31 can further improve the adhesion between the first metal layer 30a and the second metal layer 30b due to, for example, an anchor effect. The presence of the second metal in the grain boundaries 31 can be confirmed by elemental mapping using EDS-STEM.

The thickness of the second metal layer 30b may be 1.5 μm or more, 1.8 μm or more, or 2.0 μm or more from the viewpoint of high conductivity. The thickness of the second metal layer 30b may be 10 μm or less, 8 μm or less, or 6 μm or less. The thickness of the portion of the conductive layer 30 that contains the second metal can be considered as the thickness of the second metal layer 30b. However, the thickness of the second metal present in the grain boundaries 31 is not included in the thickness of the second metal layer 30b.

The conductive layer 30 may include the third metal layer 30c further provided between the first metal layer 30a and the second metal layer 30b as shown in FIG. 3, or may not include the third metal layer 30c. The third metal constituting the third metal layer 30c may be, for example, at least one selected from the group consisting of palladium, gold, silver, and copper, or may be palladium. The third metal layer 30c may be formed of fine metal particles containing the third metal.

The third metal may also be present in the grain boundaries 31. That is, the metal component of the third metal may penetrate the grain boundaries 31 in the first metal layer 30a. The third metal may be distributed continuously from the third metal layer 30c to the grain boundaries 31 in the first metal layer 30a. The third metal present in the grain boundaries 31 can be considered as a part of the first metal layer 30a. The presence of the third metal in the grain boundaries 31 can improve the adhesion between the first metal layer 30a and the third metal layer 30c, for example, by an anchor effect. The presence of the third metal at the grain boundaries 31 can be confirmed by elemental mapping using EDS-STEM analysis.

From the viewpoint of obtaining excellent adhesion between the first metal layer 30a and the third metal layer 30c, the depth of the third metal present in the grain boundaries 31 from the surface of the first metal layer 30a may be 40 nm or more, 30 nm or more, or 20 nm or more at maximum. From the viewpoint of high conductivity of the conductive layer 30, the depth of the third metal present in the grain boundaries 31 from the surface of the first metal layer 30a may be 200 nm or less, or 150 nm or less.

The thickness of the third metal layer 30c may be 10 nm or more, 15 nm or more, or 20 nm or more from the viewpoint of facilitating the growth of metal plating on the third metal layer 30c and from the viewpoint of high adhesion between the third metal layer 30c and the second metal layer 30b. From the viewpoint of high conductivity as the conductive layer 30, the thickness of the third metal layer 30c may be 30 nm or less, 25 nm or less, or 20 nm or less. The thickness of the portion of the conductive layer 30 that contains the third metal can be considered as the thickness of the third metal layer 30c. However, the thickness of the third metal present in the grain boundaries 31 is not included in the thickness of the third metal layer 30c.

The third metal layer 30c may have a thickness smaller than both the thickness of the first metal layer 30a and the thickness of the second metal layer 30b. The first metal layer 30a may have a thickness smaller than the thickness of the second metal layer 30b. Accordingly, the conductive film 100 tends to have excellent adhesion and excellent conductivity between the metal layers.

An electrical conductivity of the second metal of the second metal layer 30b, an electrical conductivity of the first metal of the first metal layer 30a, and an electrical conductivity of the third metal of the third metal layer 30c may become higher in this order. Accordingly, the conductive film 100 tends to have excellent conductivity.

The conductive layer 30 may further include a fourth metal layer on the second metal layer 30b, the fourth metal layer containing a metal different from the second metal. The metal constituting the fourth metal layer may contain, for example, at least one of gold and palladium.

The conductive layer 30 may have a pattern including linear portions. The pattern of the conductive layer 30 may include a plurality of linear portions arranged while extending along a certain direction. The conductive layer 30 may have a mesh-like pattern including linear portions.

The width of the linear portion of the conductive layer 30 may be 1 μm or more, 10 μm or more, or 20 μm or more and may be 90 μm or less, 70 μm or less, or 30 μm or less. In this specification, the width of the linear portion of the conductive layer 30 refers to the maximum width in the extending direction of the linear portion. From the viewpoint of improving the transparency of the conductive film 100, the width of the linear portion of the conductive layer 30 may be 0.3 μm or more, 0.5 μm or more, or 1.0 μm or more and may be 5.0 μm or less, 4.0 μm or less, or 3.0 μm or less.

The thickness of the conductive layer 30 may be 0.1 μm or more, 1.0 μm or more, or 2.0 μm or more and may be 10.0 μm or less, 5.0 μm or less, or 3.0 μm or less. The width and thickness of the conductive layer 30 can be adjusted by changing the design of a mold 50 described below and by changing the width and thickness of the trenches 25.

The aspect ratio of the conductive layer 30 may be, for example, 0.1 or more, 0.5 or more, or 1.0 or more and may be 10.0 or less, 7.0 or less, or 4.0 or less. The aspect ratio of the conductive layer 30 refers to the ratio of the thickness of the conductive layer 30 to the width of the conductive layer 30 (thickness/width).

The base material 1 may be a transparent base material and particularly may be a transparent resin film. The resin film may be, for example, a film of polyethylene terephthalate (PET), polycarbonate (PC), polyethylene naphthalate (PEN), cycloolefin polymer (COP), or polyimide (PI). The base material 1 may be glass, a Si wafer, or the like. The base material 1 may have a degree of light transparency required when the conductive film 100 is incorporated into a display device, for example. Specifically, the total light transmittance of the base material may be 90 to 100%, and the haze of the base material may be 0 to 5%.

The thickness of the base material 1 may be 10 μm or more, 20 μm or more, or 35 μm or more and may be 500 μm or less, 200 μm or less, or 100 μm or less.

The first resin portion 12 constituting the first resin layer 10 may be a cured product of a curable resin composition containing a curable resin. The first resin layer 10 may be transparent. Examples of curable resins include amino resins, cyanate resins, isocyanate resins, polyimide resins, epoxy resins, oxetane resins, polyesters, allyl resins, phenolic resins, benzoxazine resins, xylene resins, ketone resins, furan resins, COPNA resins, silicon resins, dicyclopentadiene resins, benzocyclobutene resins, episulfide resins, ene-thiol resins, polyazomethine resins, polyvinyl benzyl ether compounds, acenaphthylene, and ultraviolet-curable resins containing functional groups that undergo polymerization reactions when exposed to ultraviolet light, such as unsaturated double bonds, cyclic ethers, and vinyl ethers. The curable resin may be one type alone or a combination of two or more types.

The first inorganic particles 11 are dispersed in the first resin portion 12. Examples of the first inorganic particles 11 include silica, alumina, titania, tantalum oxide, zirconia, silicon nitride, barium titanate, barium carbonate, magnesium carbonate, aluminum hydroxide, magnesium hydroxide, lead titanate, lead zirconate titanate, lead lanthanum zirconate titanate, gallium oxide, spinel, mullite, cordierite, talc, aluminum titanate, barium silicate, boron nitride, calcium carbonate, barium sulfate, calcium sulfate, zinc oxide, magnesium titanate, hydrotalcite, mica, calcined kaolin, and carbon. The first inorganic particles 11 may be one type alone or a combination of two or more types.

The shape of the first inorganic particles 11 is not particularly limited, and may be, for example, spherical, ellipsoidal, polyhedral, plate-like, scaly, columnar, or the like.

A part of the plurality of first inorganic particles 11 may be present in the first metal layer 30a. First inorganic particles 11a present in the first metal layer 30a may be partially protruding from the first resin portion 12, or may be distributed within the first metal layer 30a separated from the first resin portion 12. The first inorganic particles 11a partially protruding from the first resin portion 12 or the first inorganic particles 11a separated from the first resin portion 12 are located within the first metal layer 30a, and the first metal of the first metal layer 30a is present around the protruding or separated portion. That is, a part of the plurality of first inorganic particles 11 may partially protrude from the first resin portion 12 to be partially surrounded by the first metal, and/or may be separated from the first resin portion 12 to be surrounded by the first metal within the first metal layer 30a. Furthermore, a surrounded state by the first metal does not only mean a surrounded state by the first metal only, but also means a surrounded state by the first metal, the grain boundaries 31 included in the first metal layer 30a, and the second metal or the third metal present in the grain boundaries 31. The first inorganic particles 11a separated from the first resin portion 12 can be considered as a part of the first metal layer 30a. Since the first inorganic particles 11a are present in the first metal layer 30a, the adhesion between the first resin layer 10 and the first metal layer 30a can be further improved. Further, when the first inorganic particles 11a are present in the first metal layer 30a, the grain boundaries 31 are easily formed in the first metal layer 30a.

At least a part of the plurality of first inorganic particles 11 may partially protrude from the first resin portion 12 toward the side of the second resin layer 20. The “state in which the first inorganic particles 11 partially protrude from the first resin portion 12 toward the side of the second resin layer 20” means a state in which a part of the surface of the first inorganic particles 11 protrudes from the first resin portion 12 toward the side of the second resin layer 20 and is in contact with the second resin layer 20. That is, a plurality of the first inorganic particles 11 that partially protrude toward the side of the second resin layer 20 may be in a state in which the portions protruding toward the side of the second resin layer 20 are not covered by the first resin portion 12 (the portions protruding toward the side of the second resin layer 20 are exposed from the first resin portion 12). Hereinafter, such first inorganic particles are also referred to as “exposed first inorganic particles”. The exposed first inorganic particles 11a can contribute to improving the adhesion between the first resin layer 10 and the second resin layer 20. The presence of the exposed first inorganic particles 11a can be confirmed, for example, by observing a cross section of the conductive film 100 along the thickness direction with a TEM. The first inorganic particles 11 may include first inorganic particles 11b that are embedded in the first resin portion 12 and do not protrude toward the side of the second resin layer 20 (are not exposed from the first resin portion 12).

From the viewpoint of excellent adhesion between the first resin layer 10 and the second resin layer 20 of the conductive film 100, the ratio of the number of the exposed first inorganic particles 11a to the total number of the first inorganic particles 11 may be 10% or more. The ratio of the number of the exposed first inorganic particles 11a to the total number of first inorganic particles 11 may be, for example, 40% or less. The ratio of the number of the exposed first inorganic particles 11a is calculated by observing a cross section of the conductive film 100 along the thickness direction with a TEM and measuring the number of the exposed first inorganic particles 11a in a cross-sectional image of the first resin layer 10 within a range of 1.5 μm in any extending direction of the conductive film 100 and the number of all first inorganic particles 11 in a cross-sectional image of the first resin layer 10 within the same range.

A plurality of the first inorganic particles 11 may be unevenly distributed on the side of the second resin layer 20 in the first resin layer 10. The fact that the first inorganic particles 11 are unevenly distributed on the side of the second resin layer 20 in the first resin layer 10 can be confirmed by observing a cross section of the conductive film 100 along the thickness direction with a TEM.

The “state in which a plurality of the first inorganic particles 11 are unevenly distributed on the side of the second resin layer 20 in the first resin layer 10” means, for example, that the ratio of the number of first inorganic particles 11 (including exposed first inorganic particles 11a) present in a region A exceeds 50% of the total number of the first inorganic particles 11 in the entire first resin layer 10 when a region on the side of the second resin layer 20 from the center of the first resin layer 10 in the thickness direction in a cross section of the conductive film 100 along the thickness direction is the region A. This ratio may be 60% or more, 70% or more, 75% or more, or 80% or more.

The average particle diameter of the first inorganic particles 11 may be, for example, 10 nm or more, 15 nm or more, or 20 nm or more and may be 400 nm or less, 300 nm or less, or 200 nm or less. The average particle diameter of the first inorganic particles 11 is calculated by observing a cross section of the conductive film 100 along the thickness direction with a TEM, measuring a maximum length of each of the first inorganic particles 11 present within a range of 1.5 μm in any extending direction of the conductive film 100 in a TEM image of the cross section, and averaging the maximum lengths.

The thickness of the first resin layer 10 or the first resin portion 12 may be, for example, 30 nm or more, 50 nm or more, or 100 nm or more and may be 500 nm or less, 400 nm or less, or 300 nm or less.

The second resin layer 20 is a resin layer mainly composed of a second resin portion 22. The second resin portion 22 may be transparent. The second resin portion 22 may be a cured product of a photocurable resin or a thermosetting resin. Examples of photocurable resins or thermosetting resins include acrylic resins, amino resins, cyanate resins, isocyanate resins, polyimide resins, epoxy resins, oxetane resins, polyesters, allyl resins, phenolic resins, benzoxazine resins, xylene resins, ketone resins, furan resins, COPNA resins, silicon resins, dicyclopentadiene resins, benzocyclobutene resins, episulfide resins, ene-thiol resins, polyazomethine resins, polyvinylbenzyl ether compounds, acenaphthylene, ultraviolet-curable resins containing functional groups that undergo polymerization reactions when exposed to ultraviolet light, such as unsaturated double bonds, cyclic ethers, and vinyl ethers. These photocurable resins or thermosetting resins may be one type alone or a combination of two or more types.

The second resin layer 20 may contain second inorganic particles. The second inorganic particles may be one or more type of inorganic particles selected from Pd, Cu, Ni, Co, Au, Ag, Pd, Rh, Pt, In, and Sn, and may contain Pd. The second inorganic particles may be one type alone or a combination of two or more types of inorganic particles. The second inorganic particles may also be included in the first metal layer 30a.

The shape of the second inorganic particles is not particularly limited, and may be, for example, spherical, ellipsoidal, polyhedral, plate-like, scaly, columnar, or the like.

From the viewpoint of excellent transparency of the conductive film 100, the average particle diameter of the second inorganic particles may be 10 nm or less, 8 nm or less, or 5 nm or less. The average particle diameter of the second inorganic particles may be, for example, 0.1 nm or more, 0.5 nm or more, or 1 nm or more. The average particle diameter of the second inorganic particles is calculated by observing a cross section of the conductive film 100 along the thickness direction with a TEM, measuring a maximum length of each of the second inorganic particles present within a range of 1.5 μm in any extending direction of the conductive film 100 in a TEM image of the cross section, and averaging the maximum lengths.

The average particle diameter of the second inorganic particles may be smaller than the average particle diameter of the first inorganic particles 11. The ratio of the average particle diameter of the second inorganic particles to the average particle diameter of the first inorganic particles 11 (the average particle diameter of the second inorganic particles/the average particle diameter of the first inorganic particles 11) may be 0.3 or less, or 0.1 or less and may be 0.01 or more, 0.02 or more, or 0.05 or more.

A plurality of the second inorganic particles may be unevenly distributed on the side of the first resin layer 10 in the second resin layer 20. The “state in which a plurality of the second inorganic particles are unevenly distributed on the side of the first resin layer 10 in the second resin layer 20” means, for example, that the ratio of the number of the second inorganic particles in a region B exceeds 50% of the total number of the second inorganic particles in the entire second resin layer 20 when a region on the side of the first resin layer 10 from the center of the second resin layer 20 in the thickness direction in an observation image obtained by observing a cross section of the conductive film 100 in the thickness direction with a TEM is the region B. This ratio may be 80% or more, 90% or more, or 95% or more.

From the viewpoint of excellent transparency of the conductive film 100, the second inorganic particles, which correspond to 80% or more of the total number of the second inorganic particles, may be distributed within a region whose distance from the interface between the first resin layer 10 and the second resin layer 20 is ⅓ or less, ¼ or less, or ⅕ or less of the thickness of the first resin layer 10. The second inorganic particles, which correspond to 90% or more or 95% or more of the total number of the second inorganic particles, may be distributed within a region whose distance from the interface between the first resin layer 10 and the second resin layer 20 is ⅓ or less, ¼ or less, or ⅕ or less of the thickness of the first resin layer 10. The “interface between the first resin layer 10 and the second resin layer 20” means the interface between the first resin portion 12 and the second resin portion 22, and the interface between the exposed first inorganic particles 11a and the second resin portion 22.

From the viewpoint of excellent transparency of the conductive film 100, 80% or more of the second inorganic particles relative to the total number of the second inorganic particles may be distributed within a region whose distance from the interface between the first resin layer 10 and the second resin layer 20 is 70 nm or less, 65 nm or less, 60 nm or less, 55 nm or less, 50 nm or less, 45 nm or less, 40 nm or less, 35 nm or less, 30 nm or less, 25 nm or less, 20 nm or less, 15 nm or less, or 10 nm or less. 90% or more or 95% or more of the second inorganic particles relative to the total number of the second inorganic particles may be distributed within a region whose distance from the interface between the first resin layer 10 and the second resin layer 20 is 70 nm or less, 65 nm or less, 60 nm or less, 55 nm or less, 50 nm or less, 45 nm or less, 40 nm or less, 35 nm or less, 30 nm or less, 25 nm or less, 20 nm or less, 15 nm or less, or 10 nm or less.

A plurality of the second inorganic particles may be present in the periphery of each of the plurality of exposed first inorganic particles 11a protruding (exposed) toward the side of the second resin layer 20. In this case, the adhesion between the first resin layer 10 and the second resin layer 20 can be further improved. The “periphery of the portion of each of the first inorganic particles 11a protruding toward the side of the second resin layer 20” may refer to a region within 10 nm from the surface of the portion of each of the first inorganic particles 11a protruding toward the side of the second resin layer 20. A portion of one exposed first inorganic particle 11a protruding toward the side of the second resin layer 20 may be in contact with a plurality of the second inorganic particles.

The trench 25 opens on the surface opposite to the first resin layer 10 and extends onto the second resin layer 20. The trench 25 includes a portion that forms a pattern corresponding to the pattern of the conductive layer 30. As shown in FIG. 2, the width of the trench 25 may become narrow from the second resin layer 20 opposite to the side of the first resin layer 10 toward the side of the first resin layer 10 and the width of the trench 25 may be substantially constant in the depth direction.

The width and depth of the trench 25 typically and substantially correspond to the width and thickness of the conductive layer 30, respectively. In this specification, the width of the trench 25 means the maximum width in a direction perpendicular to the thickness direction of the conductive film 100 (the extending direction of the conductive film 100), and the depth of the trench 25 means the maximum depth in the thickness direction of the conductive film 100. The ratio of the depth of the trench 25 to the width of the trench 25 may be similar to the aspect ratio of the conductive layer 30 described above.

The thickness of the second resin layer 20 or the thickness of the second resin portion 22 may be, for example, 1 μm or more, 1.5 μm or more, or 2 μm or more and may be 5 μm or less, 4 μm or less, or 3 μm or less.

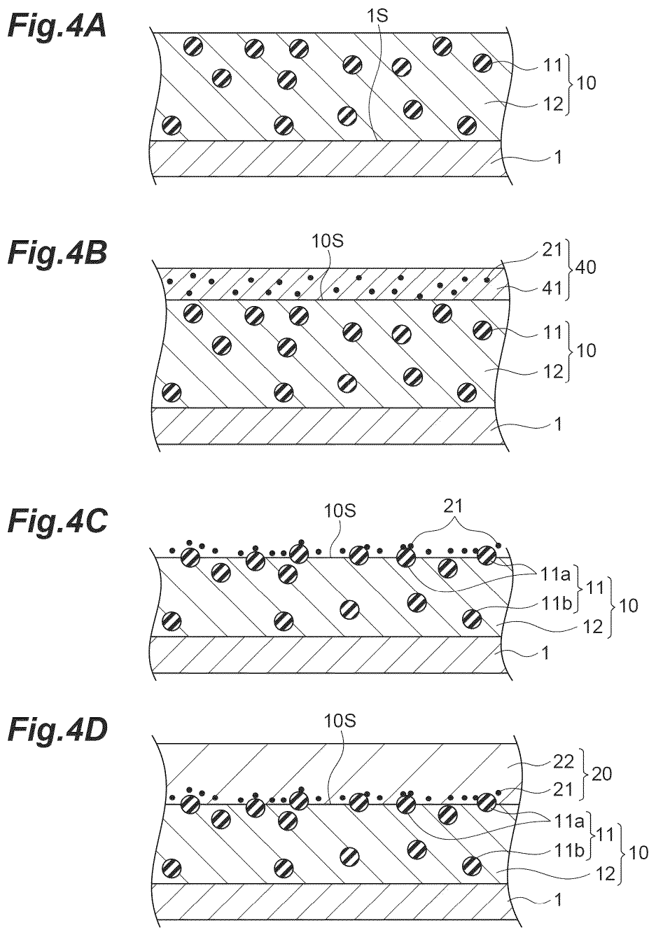

FIGS. 4A to 6C are cross-sectional views schematically showing an example of a method for manufacturing the conductive film 100 shown in FIG. 1. In the method according to this embodiment, first, as shown in FIG. 4A, the first resin layer 10 containing the first inorganic particles 11 is formed on one surface 1S of the film-like base material 1. The first resin layer 10 is formed, for example, by a method including applying a coating liquid containing a resin component forming the first resin portion 12, the first inorganic particles 11, and a solvent onto the base material 1, and removing the solvent from the coating on the base material 1. The step of FIG. 4A may be a step of preparing a laminate including the base material 1 and the first resin layer 10 formed on the base material 1.

As shown in FIG. 4B, a second inorganic particle containing layer 40 is formed on the surface 10S of the first resin layer 10 opposite to the base material 1. The second inorganic particle containing layer 40 is a layer containing second inorganic particles 21 and a third resin portion 41. The third resin portion 41 may be formed of the same material as the second resin portion 22. The step of FIG. 4B may be a step of preparing a laminate in which the base material 1, the first resin layer 10, and the second inorganic particle containing layer 40 are provided in this order.

As shown in FIG. 4C, the first inorganic particles 11 are exposed from the surface 10S of the first resin layer 10. As a method for exposing the first inorganic particles 11 from the surface 10S, for example, a method can be exemplified which performs an ashing process on the laminate of FIG. 4B to remove a part of the third resin portion 41 in the second inorganic particle containing layer 40 and the first resin portion 12 in the first resin layer 10. As a result of the ashing process, the first resin layer 10 becomes thinner than it was at the time of FIG. 4B. Although a part of the first resin portion 12 is removed by the ashing process, the first inorganic particles 11 present on the first resin portion 12 are not removed and remain on the first resin layer 10 opposite to the base material 1. Therefore, it is possible to form the first resin layer 10 in which the first inorganic particles 11 are unevenly distributed on the side opposite to the base material 1. The third resin portion 41 in the second inorganic particle containing layer 40 may be entirely removed by the ashing process or a part of the third resin portion 41 may remain on the surface 10S of the first resin layer 10. Since the third resin portion 41 in the second inorganic particle containing layer 40 is removed, the second inorganic particles 21 in the second inorganic particle containing layer 40 are deposited on the surface 10S of the first resin layer 10. The deposited second inorganic particles 21 may be attached to the first resin portion 12 or the exposed first inorganic particles 11a. The step of FIG. 4C may be a step of removing a part of the first resin portion 12 in the first resin layer 10 and the third resin portion 41 in the second inorganic particle containing layer 40 to expose a plurality of the first inorganic particles 11 onto the surface 10S of the first resin layer 10.

As shown in FIG. 4D, the second resin layer 20 is formed on the surface 10S of the first resin layer 10. Specifically, a resin composition containing a resin component forming the second resin portion 22 is applied onto the surface 10S of the first resin layer 10 on which the second inorganic particles 21 are deposited, thereby forming the second resin layer 20 containing the second resin portion 22 and the second inorganic particles 21. Here, when a part of the third resin portion 41 in the second inorganic particle containing layer 40 remains on the surface 10S of the first resin layer 10, the remaining third resin portion 41 becomes a part of the second resin portion 22 in the second resin layer 20. The step of FIG. 4D may be a step of preparing a laminate in which the base material 1, the first resin layer 10, and the second resin layer 20 are provided in this order.

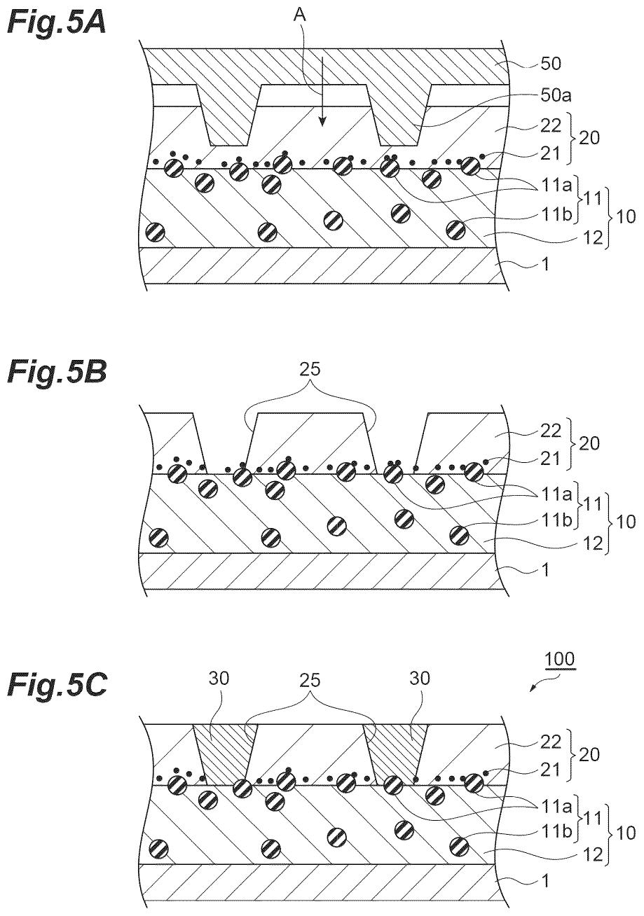

As shown in FIGS. 5A and 5B, the trench (groove portion) 25 is formed in the second resin layer 20 by an imprint method using the mold 50 having a convex portion 50a. In this step, the mold 50 with the convex portion 50a having a predetermined shape is moved in the direction indicated by arrow A to press the mold 50 into the second resin layer 20 (FIG. 5A). The mold 50 may be pressed until the tip of the convex portion 50a reaches the first resin layer 10. In this state, the second resin portion 22 is cured as necessary. When the uncured second resin portion 22 contains a photocurable resin, the second resin portion 22 is cured by irradiating the second resin portion with light such as ultraviolet light. Then, the mold 50 is removed to form the trench 25 having a shape obtained by reversing the shape of the convex portion 50a of the mold 50 (FIG. 5B). The method for forming the trench 25 is not limited to the imprint method. For example, the trench 25 may be formed by a laser, dry etching, or photolithography. The trench 25 extends on the first resin layer 10 to form a pattern corresponding to the conductive layer 30. In order to expose the second inorganic particles 21 on the bottom surface of the trench 25, the second resin portion 22 remaining on the first resin layer 10 in the trench 25 may be removed by etching such as dry etching after removing the mold 50. The step of FIGS. 5A and 5B may be a step of forming the trench 25 that opens to the surface of the second resin layer 20 opposite the first resin layer 10 in the laminate in which the base material 1, the first resin layer 10, and the second resin layer 20 are provided in this order.

The mold 50 may be formed of quartz, Ni, ultraviolet curable liquid silicone rubber (PDMS), or the like. The shape of the convex portion 50a of the mold 50 is designed according to the shape of the trench 25 to be formed.

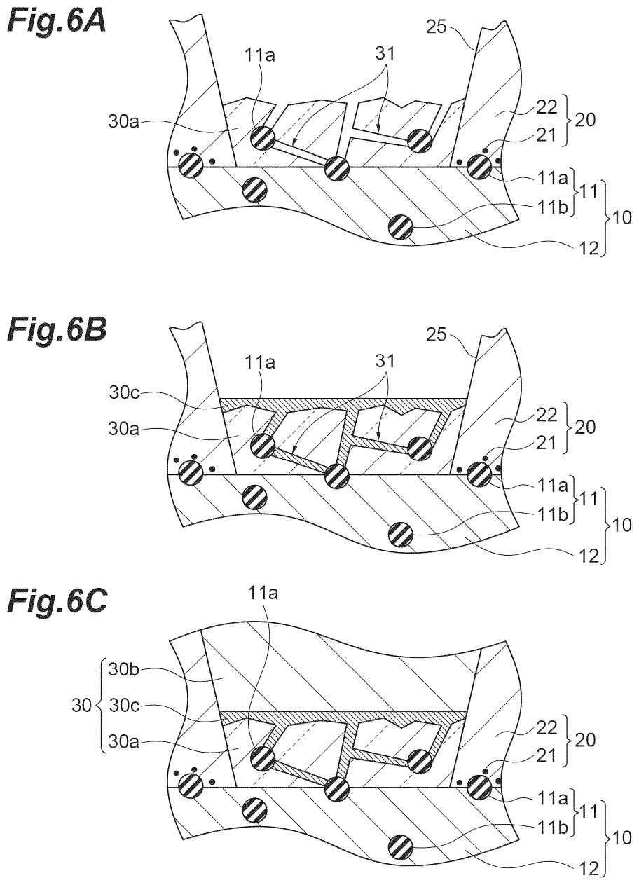

As shown in FIG. 5C, the conductive layer 30 is formed to fill the trench 25. By forming the conductive layer 30 filling the trench 25, the conductive film 100 can be obtained. A method for forming the conductive layer 30 is shown, for example, in FIGS. 6A to 6C.

First, as shown in FIG. 6A, the first metal layer 30a is formed on the bottom of the trench 25 of the laminate having the trench 25. The first metal layer 30a can be formed by immersing the laminate having the trench 25 in a first electroless plating solution containing ions of the metal that constitutes the first metal layer 30a. The step of FIG. 6A may be a step of preparing a laminate in which the base material 1, the first resin layer 10, the second resin layer 20 having the trench 25 opening to a surface opposite to the first resin layer 10, and the first metal layer 30a having the trench 25 are provided in this order.

The first electroless plating solution contains ions of the metal that constitutes the first metal layer 30a. The first electroless plating solution may further contain phosphorus, boron, iron, and the like.

The temperature of the first electroless plating solution when the laminate is immersed in the first electroless plating solution may be, for example, 40 to 80° C. The immersion time in the first electroless plating solution varies depending on the thickness of the first metal layer 30a and other factors, but may be, for example, 1 to 10 minutes.

As shown in FIG. 6B, the third metal layer 30c is formed on the first metal layer 30a. The third metal layer 30c can be formed by immersing the laminate having the first metal layer 30a in an aqueous solution containing the metal that constitutes the third metal layer 30c. The step of FIG. 6B may be a step of preparing a laminate in which the base material 1, the first resin layer 10, the second resin layer 20 having the trench 25 opening to a surface opposite to the first resin layer 10, the first metal layer 30a formed on the trench 25, and the third metal layer 30c formed on the first metal layer 30a are provided in this order.

The aqueous solution contains the metal that constitutes the third metal layer 30c. The temperature of the aqueous solution when the laminate is immersed in the aqueous solution may be, for example, 20 to 60° C. The immersion time in the aqueous solution varies depending on the thickness of the third metal layer 30c and other factors, but may be, for example, 1 to 10 minutes.

As shown in FIG. 6C, the second metal layer 30b is formed on the third metal layer 30c. The second metal layer 30b can be formed by immersing the laminate on which the third metal layer 30c is formed in a second electroless plating solution containing ions of the metal that constitutes the second metal layer 30b. The step of FIG. 6C may be a step of preparing a laminate in which the base material 1, the first resin layer 10, the second resin layer 20 having the trench 25 opening to a surface opposite to the first resin layer 10, the first metal layer 30a formed on the trench 25, the third metal layer 30c formed on the first metal layer 30a, and the second metal layer 30b formed on the third metal layer 30c are provided in this order. When the conductive layer 30 does not include the third metal layer 30c, the second metal layer 30b can be formed on the first metal layer 30a by immersing the laminate having the first metal layer 30a in a second electroless plating solution containing ions of the metal that constitutes the second metal layer 30b.

The second electroless plating solution contains ions of the metal that constitutes the second metal layer 30b. The second electroless plating solution may further contain formalin or the like.

The temperature of the second electroless plating solution when the laminate is immersed in the second electroless plating solution may be, for example, 30 to 60° C. The immersion time in the second electroless plating solution varies depending on the thickness of the second metal layer 30b and other factors, but may be, for example, 2 to 20 minutes.

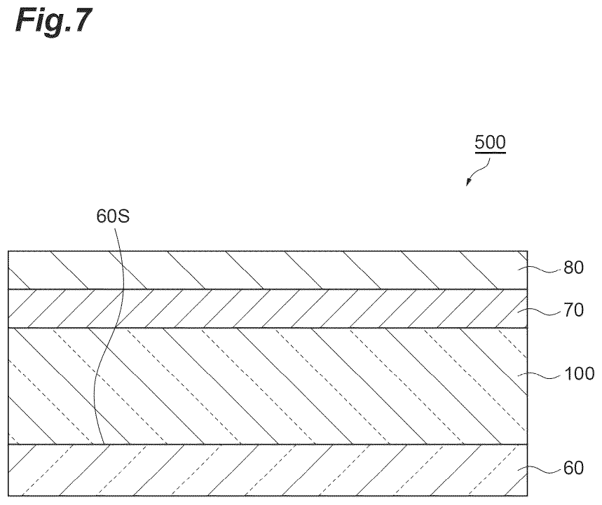

The conductive film described above can be incorporated into a display device as, for example, a planar transparent antenna. The display device may be, for example, a liquid crystal display device or an organic EL display device. FIG. 7 is a cross-sectional view showing an embodiment of a display device incorporating the conductive film 100. A display device 500 shown in FIG. 7 includes an image display unit 60 having an image display region 60S, the conductive film 100, a polarizing plate 70, and a cover glass 80. The conductive film 100, the polarizing plate 70, and the cover glass 80 are laminated in this order from the image display unit 60 on the side of the image display region 60S of the image display unit 60.

The configuration of the display device is not limited to the form shown in FIG. 7 and can be appropriately changed as necessary. For example, the polarizing plate 70 may be provided between the image display unit 60 and the conductive film 100. The image display unit 60 may be, for example, a liquid crystal display unit. The polarizing plate 70 and the cover glass 80 may be any of those commonly used in display devices. The polarizing plate 70 and the cover glass 80 may not be essentially provided.

Although a display device has been exemplified as a device to which the conductive film is applied, the conductive film may be applied to devices other than the display device. For example, a conductive film may be applied to the glass of a building, an automobile, and the like as a transparent antenna.

The technology according to the present disclosure includes the following configuration examples, but is not limited to these.

A conductive film according to an aspect of the present disclosure is a conductive film including: a film-like base material; and a conductive layer provided on one main surface side of the base material, wherein the conductive layer includes a first metal layer containing a first metal, and a second metal layer containing a second metal different from the first metal, provided in order from the base material side, and wherein the first metal layer includes grain boundaries.

According to the conductive film, since the first metal layer includes grain boundaries, the surface area of the first metal layer increases and hence the adhesion between the first metal layer and other metal layers is improved.

In the conductive film, the second metal may be also present in the grain boundaries. Accordingly, the adhesion between the first metal layer and other metal layers is further improved due to the anchor effect of the second metal present in the grain boundaries while improving the electrical conductivity of the conductive layer.

In the conductive film, the conductive layer may further include a third metal layer which is provided between the first metal layer and the second metal layer and contains a third metal different from the first metal and the second metal. Accordingly, since the stress applied to the conductive film is dispersed by forming a multi-layered conductive layer, the adhesion between the first metal layer and the third metal layer and between the second metal layer and the third metal layer is further improved.

In the conductive film, the third metal may be present in the grain boundaries. Accordingly, the adhesion between the first metal layer and the third metal layer is further improved due to the anchor effect of the third metal present in the grain boundaries.

In the conductive film, an electrical conductivity of the second metal, an electrical conductivity of the first metal, and an electrical conductivity of the third metal may increase in this order. Accordingly, the conductive film tends to have excellent conductivity.

In the conductive film, the third metal layer may have a thickness smaller than both of the thickness of the first metal layer and the thickness of the second metal layer. Accordingly, the conductive film tends to have excellent adhesion and excellent conductivity between the metal layers.

The conductive film may further include: a resin layer provided between the base material and the conductive layer and containing a plurality of inorganic particles. Accordingly, the adhesion of the conductive layer to the base material is further improved.

In the conductive film, a part of the plurality of inorganic particles may partially protrude from the resin portion to be partially surrounded by the first metal. Further, a part of the plurality of inorganic particles may be separated from the resin portion to be surrounded by the first metal within the first metal layer. Accordingly, the adhesion between the conductive layer and the resin layer is further improved.

In the conductive film, the conductive layer may have a pattern including linear portions. Accordingly, the conductive film tends to have excellent transparency.

Further, a display device according to an aspect of the present disclosure includes the conductive film.

According to the display device, a display device having a conductive film with high adhesion between metal layers can be obtained.

The present disclosure includes, for example, the following [1] to [12].

[1] A conductive film including:
a film-like base material; and
a conductive layer provided on one main surface side of the base material,
wherein the conductive layer includes a first metal layer containing a first metal, and a second metal layer containing a second metal different from the first metal, provided in order from the base material side, and
wherein the first metal layer includes grain boundaries.

[2] The conductive film according to [1],
wherein the second metal is also present in the grain boundaries.

[3] The conductive film according to [1],
wherein the conductive layer further includes a third metal layer containing a third metal different from the first metal and the second metal, provided between the first metal layer and the second metal layer.

[4] The conductive film according to [3],
wherein the third metal is also present in the grain boundaries.

[5] The conductive film according to [2],
wherein the conductive layer further includes a third metal layer containing a third metal different from the first metal and the second metal, provided between the first metal layer and the second metal layer.

[6] The conductive film according to [5],
wherein the third metal is also present in the grain boundaries.

[7] The conductive film according to any one of [3] to [6],
wherein an electrical conductivity of the second metal, an electrical conductivity of the first metal, and an electrical conductivity of the third metal increase in this order.

[8] The conductive film according to any one of [3] to [7],
wherein the third metal layer has a thickness smaller than both of the thickness of the first metal layer and the thickness of the second metal layer.

[9] The conductive film according to any one of [1] to [8], further including:
a resin layer containing a resin portion and a plurality of inorganic particles, provided between the base material and the conductive layer.

[10] The conductive film according to [9],
wherein a part of the plurality of inorganic particles partially protrudes from the resin portion to be partially surrounded by the first metal and/or is separated from the resin portion to be surrounded by the first metal within the first metal layer.

[11] The conductive film according to any one of [1] to [10],
wherein the conductive layer has a pattern including linear portions.

[12] A display device including:
the conductive film according to [11].

### EXAMPLES

The present disclosure is not limited to the following examples.

### Example 1

A coating liquid for forming a first resin layer containing silica particles (average particle size: 100 nm), an acrylic resin, and a solvent was prepared. This coating liquid was applied onto a COP film (thickness: 100 μm), and the solvent was removed from the coating on the COP film in a hot air drying oven. Next, the coating was irradiated with ultraviolet light using a UV treatment device to cure the coating, thereby forming a first resin layer having a thickness of 300 μm and containing a first resin portion and silica particles (first inorganic particles) on the COP film.

A coating liquid for forming a second inorganic particle containing layer was prepared, which contained Pd fine particles (average particle diameter: 5 nm), an acrylic resin, and a solvent. This coating liquid was applied onto the first resin layer, and the solvent was removed from the coating on the first resin layer in a hot air drying oven. Next, the coating was irradiated with ultraviolet rays using a UV treatment device to cure the coating, and a second inorganic particle containing layer containing Pd fine particles (second inorganic particles) and having a thickness of 60 μm was formed on the first resin layer, thereby obtaining a laminate.

The laminate after the formation of the second inorganic particle containing layer was placed in a vacuum device, and the surface of the second inorganic particle containing layer was subjected to an ashing process to remove the resin portion in the second inorganic particle containing layer and the resin portion in the surface layer of the first resin layer. The thickness of the first resin layer after the ashing process was 260 μm.

A UV curable resin was applied to the surface of the first resin layer after the ashing process to form a coating having a thickness of 2 μm. Next, a mold having convex portions was pressed into this coating so that the tips of the convex portions of the mold reached the surface of the first resin layer, and in this state the coating was irradiated with ultraviolet light to cure the coating. The mold was removed from the cured coating to form a second resin layer having linear trenches that intersected each other, opened on the surface opposite the first resin layer, and had a mesh-like pattern.

The laminate after the formation of the second resin layer was placed in a vacuum device and subjected to an ashing process to remove the resin constituting the second resin layer remaining at the bottom of the trench.

Next, the laminate was immersed in an electroless plating solution containing nickel sulfate and sodium hypophosphite to grow Ni plating from the surface of the first resin layer and form a Ni layer (first metal layer) in the trench.

The laminate on which the Ni layer was formed was immersed in an aqueous solution containing Pd. Next, the obtained laminate was immersed in an electroless plating solution containing copper sulfate and formalin to grow Cu plating on the Ni layer starting from the Pd layer and form a Cu layer (second metal layer) in the trench. Accordingly, a conductive layer having a mesh-like pattern including a Ni layer, a Pd layer, and a Cu layer was formed in the trench to form a conductive film. The thicknesses of the Ni, Pd, and Cu layers were 100 nm, 30 nm, and 2 μm in the order, respectively.

In order to observe a cross section along the thickness direction of the obtained conductive film, a portion including a conductive layer of the conductive film was cut into a plate shape using a focused ion beam (FIB) and subjected to a thin-sectioning process to obtain a sample for TEM observation. The prepared sample was observed in bright field using a TEM (Product Name: JEM-2011F) at an accelerating voltage of 200 kV as conditions, and it was confirmed that grain boundaries were formed in the Ni layer. EDS-STEM analysis confirmed that a part of the silica particles in the first resin layer was present in the Ni layer and Pd and Cu were present in the grain boundaries of the Ni layer.

### Example 2

A conductive film was prepared in the same manner as in Example 1 except that the ashing process was not performed before the formation of the first metal layer after the second resin layer was formed. When the cross section of the obtained conductive film in the thickness direction was observed by TEM, it was confirmed that grain boundaries were formed in the Ni layer. Further, EDS-STEM analysis confirmed that silica particles were present surrounded by Ni within the Ni layer and Pd and Cu were present in the grain boundaries of the Ni layer.

### Example 3

A conductive film was prepared in the same manner as in Example 1 except that the ashing process was not performed before the formation of the second resin layer after the second inorganic particle containing layer was formed. When the cross section of the obtained conductive film in the thickness direction was observed by TEM, it was confirmed that grain boundaries were formed in the Ni layer. Further, EDS-STEM analysis confirmed that silica particles were present surrounded by Ni within the Ni layer and Pd and Cu were present in the grain boundaries of the Ni layer.

### Comparative Example 1

A conductive film was prepared in the same manner as in Example 1 except that the ashing process was not performed before the formation of the second resin layer after the second inorganic particle containing layer was formed and the ashing process was not performed before the formation of the first metal layer after the second resin layer was formed. When the cross section of the obtained conductive film in the thickness direction was observed by TEM, grain boundaries of a plurality of the Ni layers were not observed.

### <Evaluation of Adhesion>

Adhesion was evaluated using the cross-cut test specified in JIS K 5600. Specifically, a notch was made with a cutter knife on the surface of the region including the second resin layer and the conductive layer to form a right-angled grid pattern (25 squares). Next, a tape was applied onto the grid pattern, the tape was brought into close contact with the surfaces of the second resin layer and the conductive layer, and then the tape was peeled off. After the tape was peeled off, the grid pattern was observed under an optical microscope. If no peeling of the conductive layer was observed, the pattern was rated as A, and if peeling of the conductive layer was observed, the pattern was rated as B. The result is shown in Table 1. In each example, no peeling was observed in the conductive layer.

TABLE 1

| | Presence or absence of ashing process | | |
|---|---|---|---|
| | After formation of first | | |
| | inorganic particle | After formation of | |
| | containing layer, | second resin layer, | |
| | Before formation of | Before formation of | |
| | second resin layer | first metal layer | Adhesion |
| Example 1 | Yes | Yes | A |
| Example 2 | Yes | No | A |
| Example 3 | No | Yes | A |
| Comparative | No | No | B |
| example 1 | | | |

### REFERENCE SIGNS LIST

1 Base material
10 First resin layer
11, 11a, 11b First inorganic particles
12 First resin portion
20 Second resin layer
21 Second inorganic particles
22 Second resin portion
25 Trench
30 Conductive layer
30a First metal layer
30b Second metal layer
30c Third metal layer
31 Grain boundary
40 Second inorganic particle containing layer
41 Third resin portion
50 Mold
60 Image display unit
70 Polarizing plate
80 Cover glass
100 Conductive film
500 Display device

1. A conductive film comprising:
a film-like base material; and
a conductive layer provided on one main surface side of the base material,
wherein the conductive layer comprises a first metal layer comprising a first metal, and a second metal layer comprising a second metal different from the first metal, provided in order from the base material side, and
wherein the first metal layer comprises grain boundaries.

2. The conductive film according to claim 1,
wherein the second metal is also present in the grain boundaries.

3. The conductive film according to claim 1,
wherein the conductive layer further comprises a third metal layer comprising a third metal different from the first metal and the second metal, provided between the first metal layer and the second metal layer.

4. The conductive film according to claim 3,
wherein the third metal is also present in the grain boundaries.

5. The conductive film according to claim 2,
wherein the conductive layer further comprises a third metal layer comprising a third metal different from the first metal and the second metal, provided between the first metal layer and the second metal layer.

6. The conductive film according to claim 5,
wherein the third metal is also present in the grain boundaries.

7. The conductive film according to claim 3,
wherein an electrical conductivity of the second metal, an electrical conductivity of the first metal, and an electrical conductivity of the third metal increase in this order.

8. The conductive film according to claim 3,
wherein the third metal layer has a thickness smaller than both of the thickness of the first metal layer and the thickness of the second metal layer.

9. The conductive film according to claim 1, further comprising:
a resin layer comprising a resin portion and a plurality of inorganic particles, provided between the base material and the conductive layer.

10. The conductive film according to claim 9,
wherein a part of the plurality of inorganic particles partially protrudes from the resin portion to be partially surrounded by the first metal and/or is separated from the resin portion to be surrounded by the first metal within the first metal layer.

11. The conductive film according to claim 1,
wherein the conductive layer has a pattern comprising linear portions.

12. A display device comprising:
the conductive film according to claim 11.
